(19) United States
(12) Patent Application Publication
(10) Pub. No.: US 2021/0013155 A1
(43) Pub. Date: Jan. 14, 2021

(54) MULTI-METAL PACKAGE STIFFENER

(71) Applicant: Flex Ltd., Singapore (SG)

(72) Inventor: Howard B. Osgood, San Jose, CA (US)

(21) Appl. No.: 16/507,268

(22) Filed: Jul. 10, 2019

(51) Int. Cl. H01L 23/00; H01L 21/48

(52) U.S. Cl. CPC H01L 23/562; H01L 23/49816; H01L 21/4846

(57) ABSTRACT

A semiconductor package system includes a semiconductor package including at least one semiconductor device having a first side and a second side and a substrate having a first side and a second side. The second side of the at least one semiconductor device is positioned on the first side of the substrate. At least one stiffener element is provided on the semiconductor package. The at least one stiffener element includes at least two metal elements having different coefficients of thermal expansion joined together.

### FIELD

The present disclosure is generally directed to stiffener elements for warpage control in electronic devices and in particular, toward semiconductor package assemblies and methods of using the stiffener elements for warpage control.

### BACKGROUND

Most active electronic components such as integrated circuits, for example, are contained in packages. These packages usually provide the dual function of protecting the electronic components while also serving as a space transformer. A semiconductor package may generally be comprised of various components such as, but not limited to, semiconductor devices, a substrate and solder material (e.g., interconnect media) such as solder for example. These various components consist of many different types of materials such as metals, plastics, organic resins and epoxies, just to name a few. In many cases, the combination of these different materials can cause the package to warp during or after a subsequent assembly process of the semiconductor package. Subsequent assembly processes or thermal exposures may further warp or deform the semiconductor package.

Warping can cause a large amount of stress on the components of the semiconductor package. If the warpage is too large, the warpage may create reliability issues regarding solder interconnections (i.e. joints) internal to the semiconductor package. Moreover, warping creates external solder joint issues between the semiconductor package and a printed circuit board on which the semiconductor package is mounted. One issue created by warping is the development of openings. Openings are created when a solder joint is formed and then subsequently breaks, when a solder joint is defectively formed and subsequently breaks, when a solder joint is not sufficiently formed (e.g., having a compromised shape or structure) and then breaks or when a solder joint is not formed at all. Thus, warping causes unwanted stress within the semiconductor package after the assembly process or during or after the semiconductor package is subsequently attached to the printed circuit board, or any combination of these three stages.

### BRIEF DESCRIPTION OF THE DRAWINGS

FIG. 1 is a diagram of an example environment in which systems and/or methods described herein may be implemented;

FIG. 2 is a diagram of an example device in FIG. 1;

FIG. 3 is a diagram of a cross-sectional view of an example semiconductor package assembly incorporating stiffener elements in accordance with one or more embodiments of the present disclosure;

FIG. 4 is a diagram of a cross-sectional view of a conventional semiconductor package assembly with a conventional lid;

FIG. 5 is a diagram of a cross-sectional view of another example semiconductor package assembly incorporating stiffener elements in accordance with one or more embodiments of the present disclosure;

FIG. 6 is a diagram of a cross-sectional view of a further example semiconductor package assembly incorporating stiffener elements in accordance with one or more embodiments of the present disclosure;

FIG. 7 is a diagram of an example top view of the example semiconductor package assembly incorporating stiffener elements illustrated in FIG. 3 in accordance with one or more embodiments of the present disclosure;

FIG. 8 is a diagram of an example top view of the example semiconductor package assembly incorporating stiffener elements illustrated in FIG. 3 in accordance with an alternative embodiment of the present disclosure;

FIG. 9 is a diagram of a top view of the example semiconductor package assembly incorporating stiffener elements illustrated in FIG. 5 in accordance with one or more embodiments of the present disclosure;

FIG. 10 is a diagram illustrating an example stiffener element at elevated temperatures;

FIG. 11 is a diagram illustrating another example stiffener element at elevated temperatures; and

FIG. 12 is a flowchart of an example process for creating a semiconductor package assembly incorporating stiffener elements in accordance with one or more embodiments of the present disclosure.

### DETAILED DESCRIPTION

Embodiments of the present disclosure will be described in connection with semiconductor package assemblies and methods of using the stiffener elements for warpage control.

The following detailed description refers to the accompanying drawings. The same reference numbers in different drawings may identify the same or similar elements.

A package may refer to one or more (e.g., two) electronic components that are grouped together into a single component. A ball grid array (BGA) is one example of a package. The BGA is a type of surface-mount package use to permanently mount devices such as microprocessors for example, whereby the entire bottom surface of the package can be used for interconnection with a printed circuit board instead of just the perimeter of the package. The description below primarily discusses the BGA package. However, the description may also apply to any other type of package, including but not limited to a connector, a flexible circuit, etc.

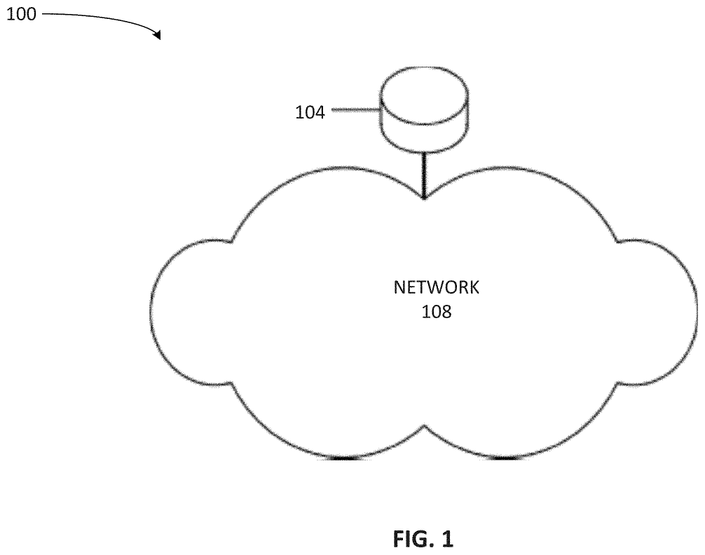

FIG. 1 is a diagram of an example environment 100 in which systems and/or methods described herein may be implemented. Environment 100 may include a device 104 and a network 108. Device 104 may include a networking device for performing network-related functions, such as a router, a server, or a switch. Alternatively, device 104 may include a computing device (e.g., a laptop computer, a desktop computer, a workstation, a notebook computer, a tablet computer, etc.); a communication device (e.g., a smart phone, a personal digital assistant (PDA), a wireless telephone, etc.); etc. that communicates via network 108.

Network 108 may include the Internet, an ad hoc network, a local area network (LAN), a wide area network (WAN), a metropolitan area network (MAN), a cellular network, a public switched telephone network (PSTN), any other network, or a combination of networks. Device 104 may communicate with other devices (not shown) and may communicate through wired and/or wireless communication links via network 108.

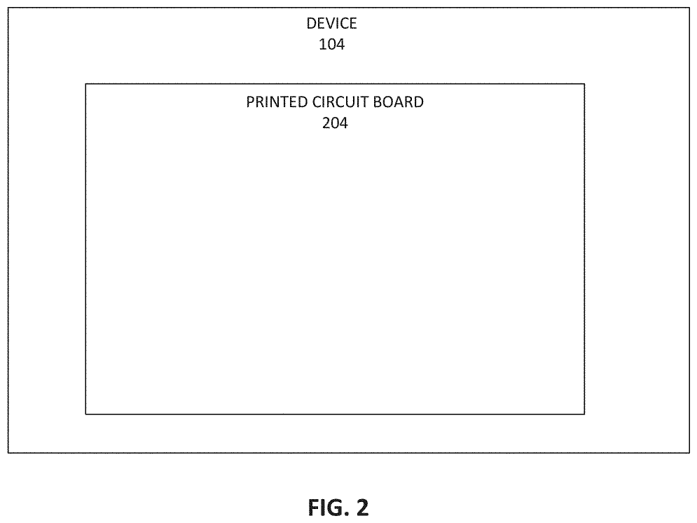

FIG. 2 is a diagram of example components of device 104. As shown, device 104 may include, for example, a printed circuit board 204 and/or one or more other printed circuit boards (not shown in FIG. 2). Printed circuit board 204 may connect multiple components, such as for example, semiconductor packages via conductive paths through which signals and power may be transmitted. For example, printed circuit board 204 mechanically supports and electrically connects semiconductor packages using conductive tracks, pads and other features etched from one or more sheets layers of copper laminated onto and/or between sheets layers of a non-conductive substrate. The semiconductor package as well as other components are generally soldered onto the printed circuit board 204 to both electrically and mechanically fasten them to it. For example, “through hole” components which typically include large component such as electrolytic capacitors and connectors are mounted by their wire leads passing through printed circuit board 204 and soldered to traces on the other side of the printed circuit board 204. “Surface-mount” components which include transistors, diodes, integrated circuit chips and packages for example, are attached by their leads to copper traces on the same side of the printed circuit board 204. According to embodiments of the present disclosure, printed circuit board 204 is designed to accommodate both methods for mounting components.

Although FIG. 2 shows example components of device 104, in other implementations, device 104 may include fewer components, different components, differently arranged components, or additional components than depicted in FIG. 2. Alternatively, or additionally, one or more components of device 104 may perform one or more other tasks described as being performed by one or more other components of device 104. For example, although FIG. 2 shows what is termed a “printed circuit board,” in one example implementation, printed circuit board 204 may be replaced with any electronics-based substrate, such as, for example, rigid-flex circuits, multichip carrier modules (MCMs), micro electro mechanical systems (MEMS), ceramic circuits, midplanes, backplanes, and/or other types of substrates.

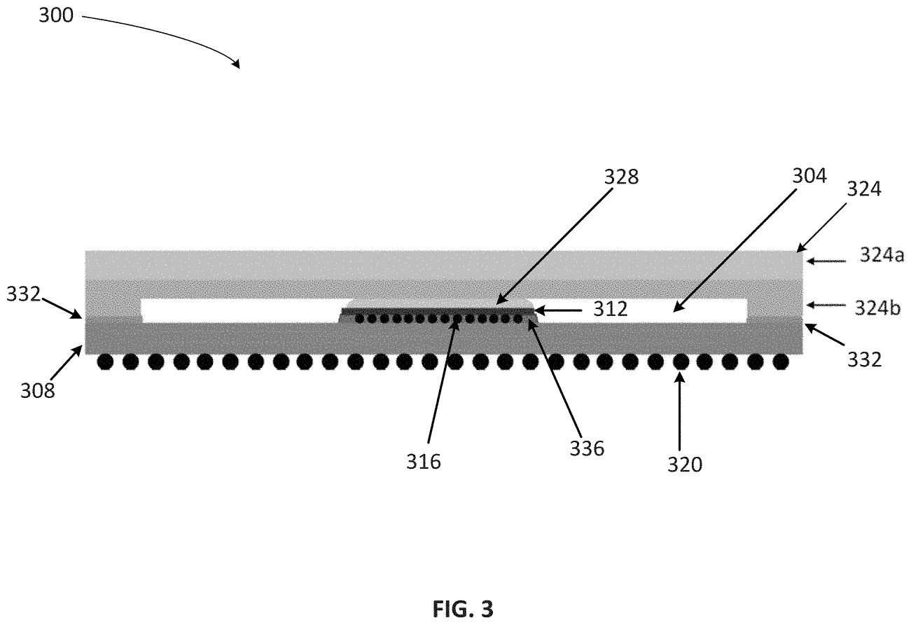

FIG. 3 is a diagram of a cross-sectional view of an example semiconductor package assembly 300 incorporating stiffener elements in accordance with one or more embodiments of the present disclosure. FIG. 3 illustrates a side view of the semiconductor package assembly 300. As shown, the semiconductor package assembly 300 includes a semiconductor package 304 which may include a package substrate 308, at least one semiconductor device 312, internal interconnections 316 and external interconnections 320. The semiconductor package assembly 300 further includes at least one stiffener element 324, thermal interface 328 and adhesive 332. In practice, semiconductor package 304 may include more components, fewer components, different components, and/or differently arranged components than are shown in FIG. 3. Package substrate 308 is typically formed of a resin multiple layer laminate such as a Bismaleimide-Triazine (BT) resin multiple layer laminate. According to an alternative embodiment of the present disclosure, package substrate 308 may include a ceramic material, a fiberglass material, and/or one or more other types of materials (e.g., epoxy). In some implementations, package substrate 308 may include an organic core BGA substrate, which may be fiberglass-based. In one example, a coefficient of thermal expansion (CTE) (e.g., in parts per million (ppm)/° C.) of package substrate 308 may match a CTE of printed circuit board 204 on an x-y plane. In another example, the CTE of package substrate 308 may match the CTE of printed circuit board 204 when a value of the CTE of package substrate 308 is approximately equal to a value of the CTE of printed circuit board 204.

The package substrate 308 includes an underfill material 336 on which the at least one semiconductor device 312 is placed. The underfill material 336 is added or dispensed subsequent to the semiconductor device 312 being mounted and is provided for stress distribution in the semiconductor package 304. A bottom portion of the at least one semiconductor device 312 is secured to a top portion of the package substrate 308 via the internal interconnections 316. Internal interconnections 316 may include an array of balls (e.g., solder balls), pins, and/or one or more other types of interconnections that connect the at least one semiconductor device 312 to the package substrate 308 for example. A top portion of the at least one semiconductor device 312 is in contact with thermal interface 328. Thermal interface 328 may be formed from a variety of interface materials such as thermally conductive compounds (e.g., thermal grease) or polymers having ceramic or metal particles designed to provide a thermal path from the top side of the semiconductor device 312 to the bottom side of the stiffener element 324. A bottom portion of the package substrate 308 includes external interconnections 320 which may include an array of balls (e.g., solder balls), pins, and/or one or more other types of interconnections that connect the semiconductor package 304 to the printed circuit board 204. At least one stiffener element 324 according to an embodiment of the present disclosure takes the form of a lid configuration and is secured to the package substrate 308 by adhesive 332.

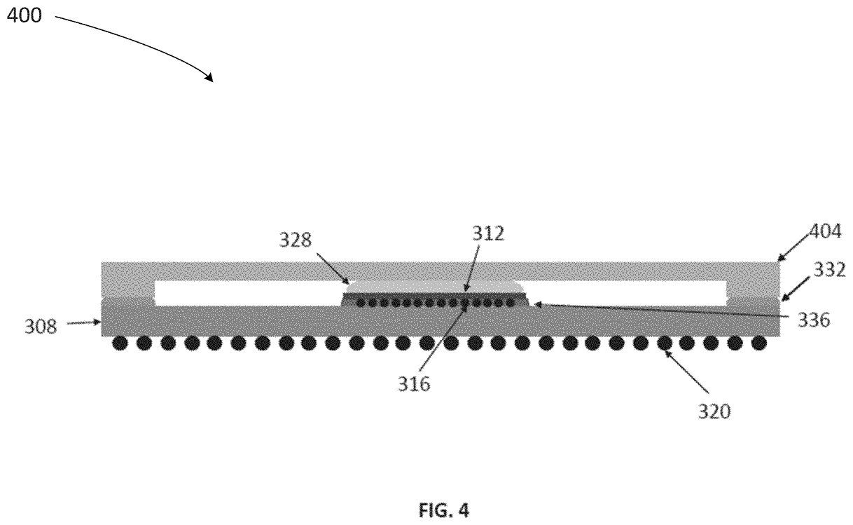

As illustrated in FIG. 4, a manufacture of a conventional lid 404 for a semiconductor package assembly 400 provides a particular metal or any other type of material that acts as a thermal conductor and also provides a protective covering for components provided on the package substrate 308 and under the lid 404. Lid 404 may take the form of a single contiguous piece of metal that spans the dimensions of the package substrate 308. The lid 404 is secured to the package substrate 308 by adhesive 332.

Referring back to FIG. 3, the at least one stiffener element 324 may be formed from at least two different types of metals or metal alloys or combinations thereof. As illustrated in FIG. 3, the at least one stiffener element 324 includes at least layers 324a and 324b. According to one embodiment of the present disclosure, layers 324a and 324b are typically joined by welding, friction welding, brazing, soldering, sintering, adhesive bonding or fastening, for example, such that the CTE for each of the layers is different.

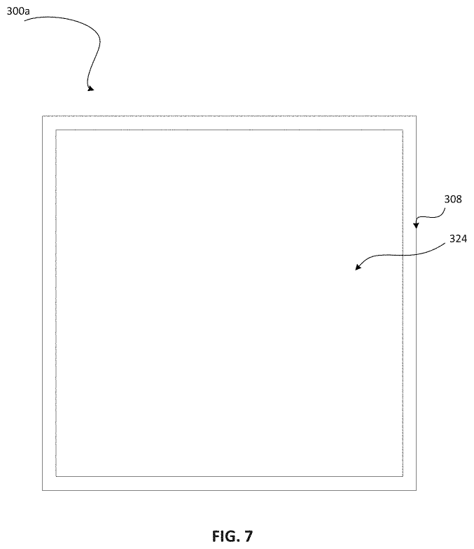

As illustrated in FIG. 7 which is a diagram of an example top view of the semiconductor package assembly 300 (labeled 300a in the figure) in accordance with one or more embodiments of the present disclosure, the at least one stiffener element 324 as illustrated in FIG. 3 may be formed from at least two materials each material being a single contiguous piece of a metal, a metal alloy or combinations thereof to span or nearly span the dimensions of the package substrate 308 to seal the semiconductor package 304. According to an alternative embodiment of the present disclosure, the at least one stiffener element 324 may be formed from at least two materials each having multiple pieces of metal, metal alloys or combinations thereof, joined together to span or nearly span the dimensions of the package substrate 308 to seal the semiconductor package 304. The stiffener element 324 is secured to the package substrate 308 by adhesive 332.

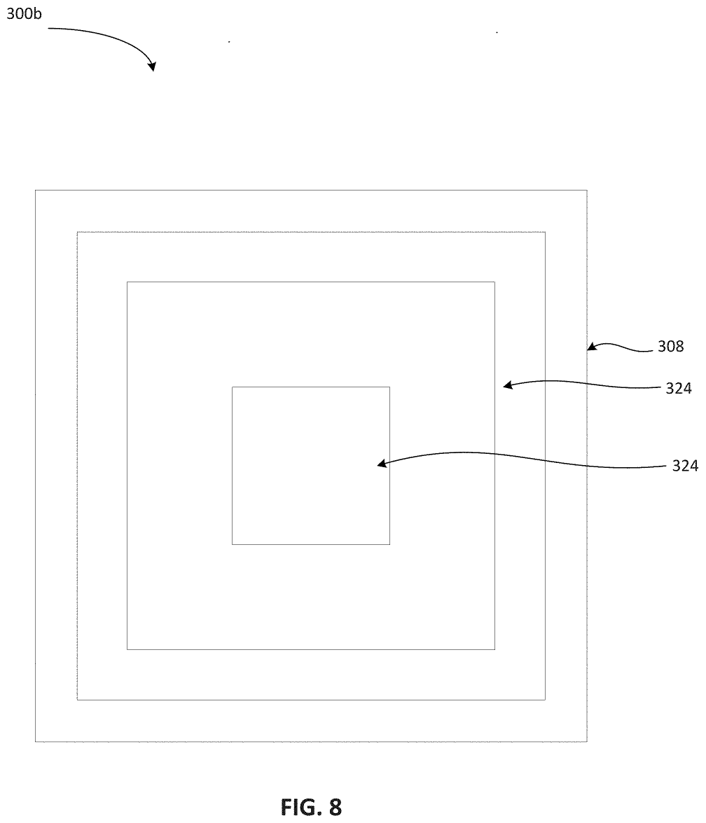

FIG. 8 is a diagram which illustrates another example top view of the semiconductor package assembly 300 (labeled 300b in the figure) in accordance with one or more embodiments of the present disclosure. Stiffener elements 324 may be formed from at least two materials each material being a single contiguous piece of a metal, a metal alloy or combinations thereof. Alternatively, stiffener elements 324 may be formed from at least two materials each having multiple pieces of metal, metal alloys or combinations thereof, joined together. As illustrated in FIG. 8, a stiffener element 324 is positioned in the center of the drawing and seals the semiconductor device 312 and another stiffener element 324 is provided between the boundary of the package substrate 308 and the sealed semiconductor device 312 and seals other components located on the package substrate. The stiffener elements 324 maybe secured to the package substrate 308 and the semiconductor device 312 by adhesive 332. The size, shape, pattern and/or location of the stiffener elements 324 are shown for illustrative purposes only and may be varied depending on the specific application as discussed in greater detail below.

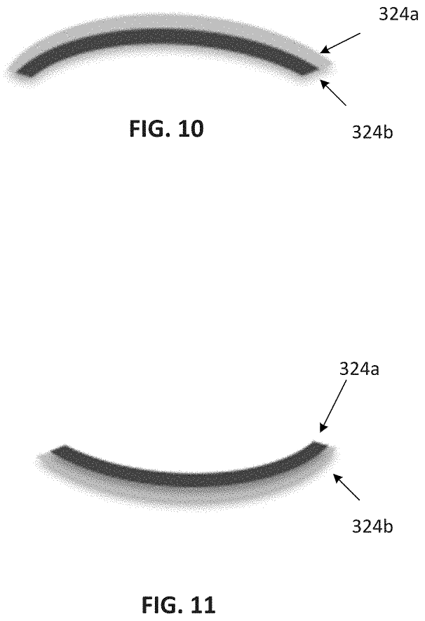

As an illustrative example in FIG. 3, layer 324a is formed from the metal alloy brass and layer 324b is formed from the metal alloy steel. The brass layer 324a has a higher CTE than the steel layer 324b. Since the brass layer 324a is positioned on top of or above the steel layer 324b, the at least one stiffener element 324 tends to bend in a direction toward the steel layer 324b as illustrated in FIG. 10 during an assembly process of the semiconductor package 304 as the stiffener element 324 is heated during subsequent thermal exposures involved in subsequent assembly processes. The degree of bend of the at least one stiffener element 324 is proportional to the length of the at least two layers 324a and 324b, the modulus of the at least two layers 324a and 324b, the thickness of each of the at least two layers 324a and 324b and the temperature reached during the assembly process. As the temperature goes down during the assembly process, the at least one stiffener element 324 bends in the opposite direction.

According to an alternative embodiment of the present disclosure, layer 324a is formed from the metal alloy steel and layer 324b is formed from the metal alloy brass. Since the brass layer 324b is under the steel layer 324a, the at least one stiffener element 324 tends to bend in a direction toward the steel layer 324a as illustrated in FIG. 11 during an assembly process of the semiconductor package 304 as the stiffener element 324 is heated during subsequent thermal exposures involved in subsequent assembly processes. Since the at least one stiffener element 324 is affixed to the package substrate 308 by the adhesive 332, this will have the effect of bending the semiconductor package 304. To counter or offset the characteristic warping of the semiconductor package 304, the at least one stiffener element 324 is designed to have semiconductor package 304 as flat as possible at the appropriate “solidus” temperature of the solder. According to one exemplary embodiment of the present disclosure, when SAC-305 solder is used for example, the “solidus” temperature is approximately 217° C. According to another exemplary embodiment of the present disclosure, the at least one stiffener element 324 is designed to exact specifications to produce a desired result in terms of the degree of bend or movement and amount of stress the at least one stiffener element 324 places on the semiconductor package 304 over a dynamic range of temperatures. The thickness of at least one of the two layers 324a and 324b can be adjusted to accommodate a specific scenario. Moreover, the lengths of the at least two layers 324a and 324b can be adjusted to accommodate a specific scenario. Since different metals and metal alloys have different CTEs the metal or metal alloy selection for each layer can be designed to produce the appropriate desired effect to cause the semiconductor package 304 to be as flat as possible at the target temperature or temperature range during the assembly process of the semiconductor package.

Controlling the warpage or deformation of the at least one stiffener element 324 depends on many factors. For example, different thicknesses of each of the at least two layers 324a and 324b controls the amount of bend of the at least one stiffener element 324. Another example is adding an additional metal/metal alloy or combination thereof to the at least two layers 324a and 324b. The additional metal/metal alloy or combination thereof is used to either increase or decrease the bending effect at specific areas of the semiconductor package 304. Since the warpage of the semiconductor package 304 is not necessarily symmetrical, either varying the thickness of the layers or adding an additional layer, or both are used to increase or decrease the bending action at specific areas of the semiconductor package 304. The amount of force generated by the material bending is temperature and thickness dependent. Therefore in the case of adding an additional layer, the additional layer must be thick enough to make an impact on the bending of the stiffener element. The thickness of the material is exponentially more important than the CTE of the material since the CTE of the material will not have any bearing at some aspect ratio.

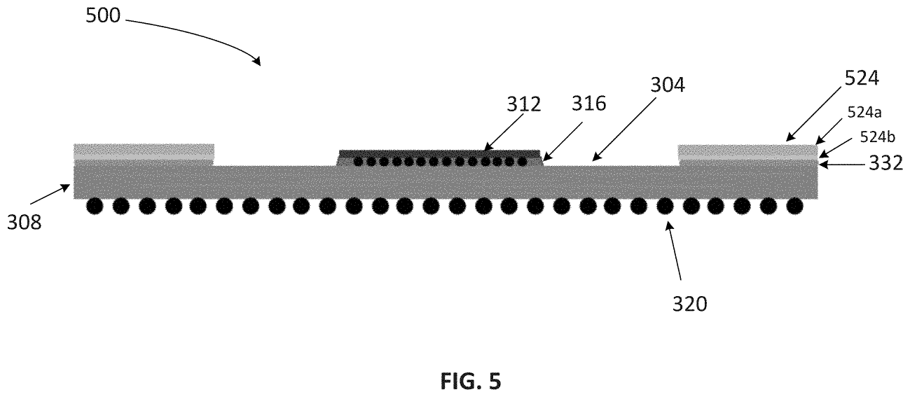

FIG. 5 is a diagram of a cross-sectional view of another example semiconductor package assembly incorporating stiffener elements in accordance with one or more embodiments of the present disclosure. As shown, the semiconductor package assembly 500 includes semiconductor package 304 which may include package substrate 308, at least one semiconductor device 312, internal interconnections 316 and external interconnections 320. Semiconductor package assembly 500 further includes at least one stiffener element 524 and adhesive 332. In practice, semiconductor package 304 may include more components, fewer components, different components, and/or differently arranged components than are shown in FIG. 5.

The at least one stiffener element 524 may be formed from at least two different types of metals or metal alloys or combinations thereof. As illustrated in FIG. 5, at least one stiffener element 524 includes at least layers 524a and 524b. According to one embodiment of the present disclosure, layers 524a and 524b are typically joined by welding, friction welding, brazing, soldering, sintering, adhesive bonding or fastening, for example. The thickness of each of the at least two layers 524a and 524b can be determined to achieve the desired results. Moreover, the proportional length of each of the at least two layers 524a and 524b can be determined to achieve the desired results.

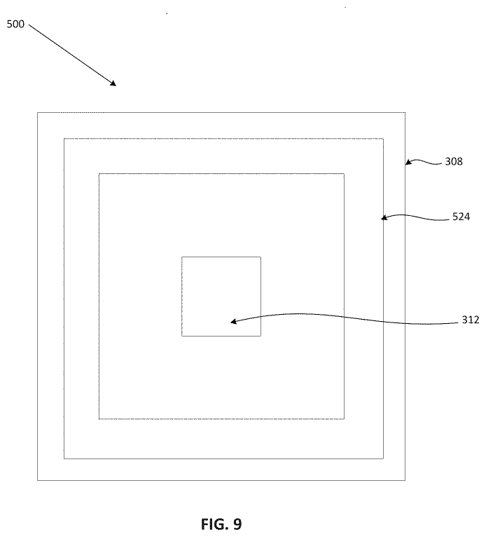

As illustrated in FIG. 9 which is a diagram of a top view of the semiconductor package assembly 500 in accordance with one or more embodiments of the present disclosure, the at least one stiffener element 524 is provided around the perimeter of the package substrate 308 with semiconductor device 312 unsealed. Stiffener element 524 may be formed from at least two materials each material being a single contiguous piece of a metal, a metal alloy or combinations thereof. Alternatively, stiffener elements 524 may be formed from at least two materials each having multiple pieces of metal, metal alloys or combinations thereof, joined together. Stiffener element 524 is provided between the boundary of the package substrate 308 and the semiconductor device 312 and seals other components located on the package substrate. The stiffener element 524 maybe secured to the package substrate 308 by adhesive 332.

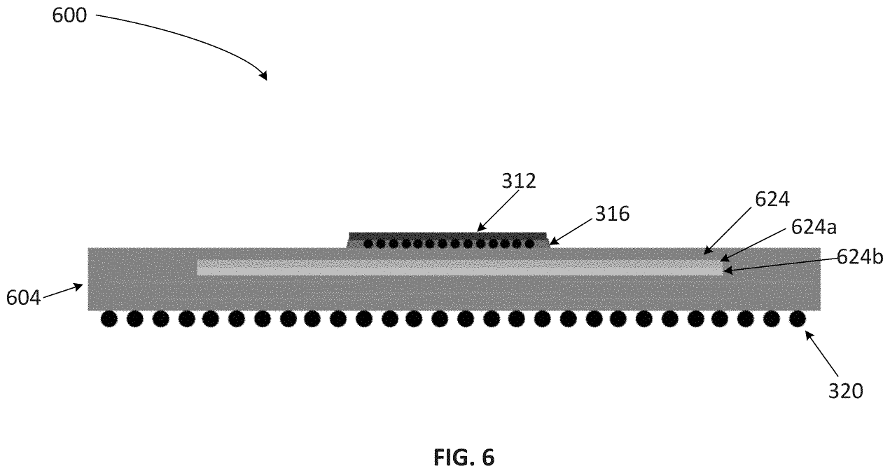

FIG. 6 is a diagram of a cross-sectional view of a further example semiconductor package assembly incorporating stiffener elements in accordance with one or more embodiments of the present disclosure. As shown, the semiconductor package assembly 600 includes package substrate 604, at least one semiconductor device 312, internal interconnections 316 and external interconnections 320. Semiconductor package assembly 600 further includes at least one stiffener element 624 provided within the package substrate 604. The at least one stiffener element 624 is incorporated into the one or more of the layers of the resin multiple layer laminate structure. The at least one stiffener element 624 may be formed from at least two different types of metals or metal alloys or combinations thereof. As illustrated in FIG. 6, the at least one stiffener element 624 includes at least layers 624a and 624b. According to one embodiment of the present disclosure, layers 624a and 624b are typically joined by welding, friction welding, brazing, soldering, sintering, adhesive bonding or fastening, for example. The thickness of each of the at least two layers 624a and 624b can be determined to achieve the desired results. Moreover, the length of each of the at least two layers 624a and 624b can be determined to achieve the desired results.

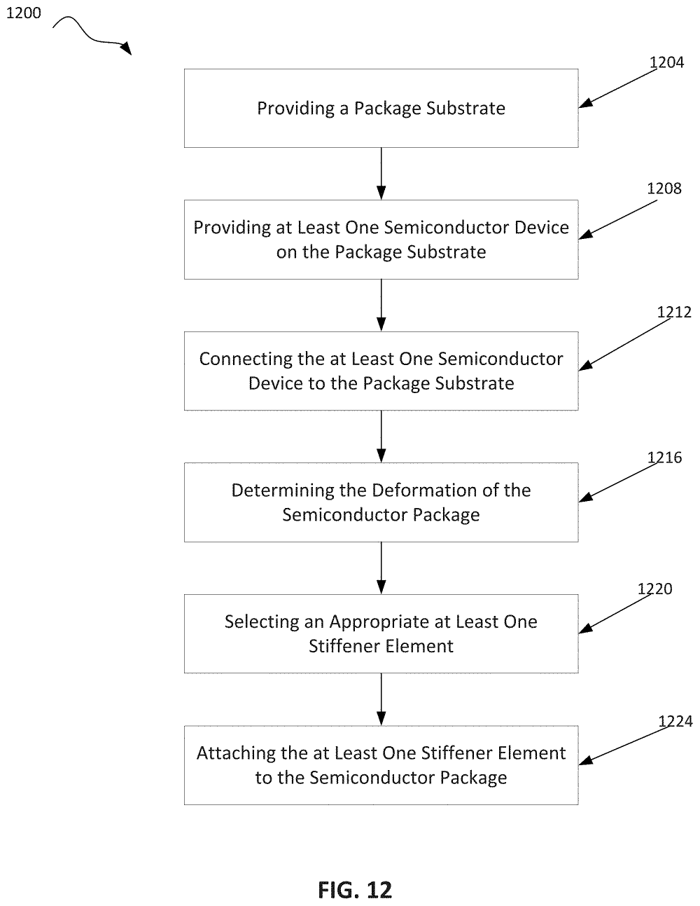

FIG. 12 is a flowchart of an example process for creating a semiconductor package assembly incorporating stiffener elements in accordance with one or more embodiments of the present disclosure. As shown in FIG. 12, process 1200 may include providing a package substrate (block 1204) and providing at least one semiconductor device on the package substrate (block 1208). Process 1200 may further include connecting the at least one semiconductor device to the package substrate (block 1212). Process 1200 may also include determining the deformation or warpage of the semiconductor package using the TherMoire process to characterize the behavior of the semiconductor package over a range of temperatures which mimic the solder reflow process when manufacturing the semiconductor package (block 1216). According to one exemplary embodiment of the present disclosure, when SAC-305 solder is used, the solidus/liquidus phase of the solder is around 217° C. to around 221° C., respectively. Once the direction and the degree to which the semiconductor package warped has been determined (e.g., the direction typically refers to either a general U-shape configuration (“smiley face”) or a general inverted U-shape configuration (“frown face”) process 1200 may include selecting appropriate at least one stiffener element (block 1220). The warpage is typically measured in a derived unit of length in an inch-based system of units referred to as mils whereby one mil is equal to one thousandth of an inch. According to one exemplary embodiment of the present disclosure, the direction of either the general U-shape configuration (“smiley face”) or the general inverted U-shape configuration (“frown face”) is measured from the lowest to the highest point with respect to a datum based on a predetermined number of the tallest BGA balls (i.e., the plane that the BGA part would sit on if the balls were place on a flat surface).

The at least one stiffener element is selected to oppose the direction and degree to which the semiconductor package warped such that the semiconductor package remains as flat as possible at the solidus temperature of the solder. Process 1200 may also provide attaching the at least one stiffener element to the semiconductor package to form a semiconductor package assembly (block 1224).

The at least one stiffener element can be arranged in various locations on or within the semiconductor package assembly. According to one embodiment of the present disclosure, the at least one stiffener element is attached to the semiconductor package assembly in a lid configuration using a high strength and high temperature epoxy or solder. According to another embodiment of the present disclosure, the at least one stiffener element is provided around the perimeter of the package substrate of the semiconductor package assembly with the semiconductor device remaining uncovered by the at least one stiffener element. Again, the at least one stiffener element is attached to the package substrate using high strength and high temperature epoxy or solder. According to a further embodiment of the present disclosure, the at least one stiffener element is provided within the package substrate. According to other embodiments of the present disclosure, combinations of the arrangements of the at least one stiffener element are realized by the present disclosure. For example, at least one stiffener element can be provided within the package substrate and also attached to the semiconductor package assembly or provided around the perimeter of the package substrate of the semiconductor package assembly.

Any of the steps, functions, and operations discussed herein can be performed continuously and automatically.

The exemplary systems and methods of this disclosure have been described in relation to stiffener elements. However, to avoid unnecessarily obscuring the present disclosure, the preceding description omits a number of known structures and devices. This omission is not to be construed as a limitation of the scope of the claimed disclosure. Specific details are set forth to provide an understanding of the present disclosure. It should, however, be appreciated that the present disclosure may be practiced in a variety of ways beyond the specific detail set forth herein.

Furthermore, while the exemplary embodiments illustrated herein show the various components of the system collocated, certain components of the system can be located remotely, at distant portions of a distributed network, such as a LAN and/or the Internet, or within a dedicated system. Thus, it should be appreciated, that the components of the system can be combined into one or more devices, such as a server, communication device, or collocated on a particular node of a distributed network, such as an analog and/or digital telecommunications network, a packet-switched network, or a circuit-switched network. It will be appreciated from the preceding description, and for reasons of computational efficiency, that the components of the system can be arranged at any location within a distributed network of components without affecting the operation of the system.

Furthermore, it should be appreciated that the various links connecting the elements can be wired or wireless links, or any combination thereof, or any other known or later developed element(s) that is capable of supplying and/or communicating data to and from the connected elements. These wired or wireless links can also be secure links and may be capable of communicating encrypted information. Transmission media used as links, for example, can be any suitable carrier for electrical signals, including coaxial cables, copper wire, and fiber optics, and may take the form of acoustic or light waves, such as those generated during radio-wave and infra-red data communications.

While the flowcharts have been discussed and illustrated in relation to a particular sequence of events, it should be appreciated that changes, additions, and omissions to this sequence can occur without materially affecting the operation of the disclosed embodiments, configuration, and aspects.

A number of variations and modifications of the disclosure can be used. It would be possible to provide for some features of the disclosure without providing others.

In yet another embodiment, the systems and methods of this disclosure can be implemented in conjunction with a special purpose computer, a programmed microprocessor or microcontroller and peripheral integrated circuit element(s), an ASIC or other integrated circuit, a digital signal processor, a hard-wired electronic or logic circuit such as discrete element circuit, a programmable logic device or gate array such as PLD, PLA, FPGA, PAL, special purpose computer, any comparable means, or the like. In general, any device(s) or means capable of implementing the methodology illustrated herein can be used to implement the various aspects of this disclosure. Exemplary hardware that can be used for the present disclosure includes computers, handheld devices, telephones (e.g., cellular, Internet enabled, digital, analog, hybrids, and others), and other hardware known in the art. Some of these devices include processors (e.g., a single or multiple microprocessors), memory, nonvolatile storage, input devices, and output devices. Furthermore, alternative software implementations including, but not limited to, distributed processing or component/object distributed processing, parallel processing, or virtual machine processing can also be constructed to implement the methods described herein.

In yet another embodiment, the disclosed methods may be readily implemented in conjunction with software using object or object-oriented software development environments that provide portable source code that can be used on a variety of computer or workstation platforms. Alternatively, the disclosed system may be implemented partially or fully in hardware using standard logic circuits or VLSI design. Whether software or hardware is used to implement the systems in accordance with this disclosure is dependent on the speed and/or efficiency requirements of the system, the particular function, and the particular software or hardware systems or microprocessor or microcomputer systems being utilized.

In yet another embodiment, the disclosed methods may be partially implemented in software that can be stored on a storage medium, executed on programmed general-purpose computer with the cooperation of a controller and memory, a special purpose computer, a microprocessor, or the like. In these instances, the systems and methods of this disclosure can be implemented as a program embedded on a personal computer such as an applet, JAVA® or CGI script, as a resource residing on a server or computer workstation, as a routine embedded in a dedicated measurement system, system component, or the like. The system can also be implemented by physically incorporating the system and/or method into a software and/or hardware system.

Although the present disclosure describes components and functions implemented in the embodiments with reference to particular standards and protocols, the disclosure is not limited to such standards and protocols. Other similar standards and protocols not mentioned herein are in existence and are considered to be included in the present disclosure. Moreover, the standards and protocols mentioned herein and other similar standards and protocols not mentioned herein are periodically superseded by faster or more effective equivalents having essentially the same functions. Such replacement standards and protocols having the same functions are considered equivalents included in the present disclosure.

The present disclosure, in various embodiments, configurations, and aspects, includes components, methods, processes, systems and/or apparatus substantially as depicted and described herein, including various embodiments, subcombinations, and subsets thereof. Those of skill in the art will understand how to make and use the systems and methods disclosed herein after understanding the present disclosure. The present disclosure, in various embodiments, configurations, and aspects, includes providing devices and processes in the absence of items not depicted and/or described herein or in various embodiments, configurations, or aspects hereof, including in the absence of such items as may have been used in previous devices or processes, e.g., for improving performance, achieving ease, and/or reducing cost of implementation.

The foregoing discussion of the disclosure has been presented for purposes of illustration and description. The foregoing is not intended to limit the disclosure to the form or forms disclosed herein. In the foregoing Detailed Description for example, various features of the disclosure are grouped together in one or more embodiments, configurations, or aspects for the purpose of streamlining the disclosure. The features of the embodiments, configurations, or aspects of the disclosure may be combined in alternate embodiments, configurations, or aspects other than those discussed above. This method of disclosure is not to be interpreted as reflecting an intention that the claimed disclosure requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate preferred embodiment of the disclosure.

Moreover, though the description of the disclosure has included description of one or more embodiments, configurations, or aspects and certain variations and modifications, other variations, combinations, and modifications are within the scope of the disclosure, e.g., as may be within the skill and knowledge of those in the art, after understanding the present disclosure. It is intended to obtain rights, which include alternative embodiments, configurations, or aspects to the extent permitted, including alternate, interchangeable and/or equivalent structures, functions, ranges, or steps to those claimed, whether or not such alternate, interchangeable and/or equivalent structures, functions, ranges, or steps are disclosed herein, and without intending to publicly dedicate any patentable subject matter.

Embodiments include a semiconductor package system. The semiconductor package includes a semiconductor package including at least one semiconductor device having a first side and a second side and a substrate having a first side and a second side. The second side of the at least one semiconductor device is positioned on the first side of the substrate. At least one stiffener element is provided on the semiconductor package. The at least one stiffener element includes at least two metal elements having different coefficients of thermal expansion joined together.

Aspects of the above semiconductor package system include the at least one stiffener element constructed based on a determined warpage of the semiconductor package during an assembly process involving elevated temperatures. Aspects of the above semiconductor package system further include the at least one stiffener element being further constructed based on a determined direction the semiconductor package deforms during the assembly process involving elevated temperatures. Aspects of the semiconductor package system include the at least one stiffener element being attached to the first side of the substrate covering the at least one semiconductor device and the substrate. Aspects of the above semiconductor package system further include the at least one stiffener element being provided around a perimeter of the first side of the substrate leaving the first side of the at least one semiconductor device uncovered.

In addition, further aspects of the semiconductor package system include the at least one stiffener element being provided within the substrate positioned between the first and second sides of the substrate. Aspects of the semiconductor package system include the at least two metal elements being at least two metals; being at least two metal alloys; or being a combination of at least a metal and a metal alloy. Aspects of the semiconductor package system include the at least two metal elements being joined together at least by friction, friction welding, brazing, soldering, sintering, adhesive bonding or fastening.

Embodiments include a device. The device includes a circuit board having a first side and a second side and a semiconductor package system provided on the first side of the circuit board. The semiconductor package system includes a semiconductor package includes at least one semiconductor device having a first side and a second side and a substrate having a first side and a second side. The second side of the at least one semiconductor device is positioned on the first side of the substrate. The semiconductor package system further includes at least one stiffener element provided on the semiconductor package. The at least one stiffener element includes at least two metal elements having different coefficients of thermal expansion joined together.

Aspects of the above device include the at least one stiffener element being constructed based on a determined warpage of the semiconductor package during an assembly process involving elevated temperatures. Aspects of the above device also include the at least one stiffener element being further constructed based on a determined direction the semiconductor package deforms during the assembly process involving elevated temperatures. Aspects of the above device include the at least two metal elements being joined together at least by friction, friction welding, brazing, soldering, sintering, adhesive bonding or fastening. Aspects of the above device further include the at least one stiffener element being attached to the first side of the substrate covering the at least one semiconductor device and the substrate. Aspects of the above device include the at least one stiffener element being provided around a perimeter of the first side of the substrate leaving the first side of the at least one semiconductor device uncovered. Moreover, aspects of the above device include the at least one stiffener element being provided within the substrate positioned between the first and second sides of the substrate.

Embodiments include a method for forming a semiconductor package system. The method includes providing a substrate, providing at least one semiconductor device and connecting the at least one semiconductor device to the substrate to form a semiconductor package. The method further includes determining a warpage of the semiconductor package during an assembly process involving elevated temperatures, constructing at least one stiffener element based on the determined warpage during the assembly process involving elevated temperatures and providing the at least one stiffener element on the semiconductor package. The at least one stiffener element comprises at least two metal elements having different coefficients of thermal expansion joined together. Aspects of the method include adjusting the at least one stiffener element by varying a thickness of the at least one of the two metal elements to obtain a desired shape and degree of bend for the at least one stiffener element.

Aspects of the method include constructing the at least one stiffener element based on a determined direction and degree the semiconductor package deforms during the assembly process involving elevated temperatures.

The phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more,” and “at least one” can be used interchangeably herein. It is also to be noted that the terms “comprising,” “including,” and “having” can be used interchangeably.

What is claimed is:

1. A semiconductor package system, comprising:
a semiconductor package comprising:
at least one semiconductor device having a first side and a second side; and
a substrate having a first side and a second side,
wherein the second side of the at least one semiconductor device is positioned adjacent to the first side of the substrate; and
at least one stiffener element provided adjacent to the semiconductor package,
wherein the at least one stiffener element includes at least two metal elements having different coefficients of thermal expansion joined together.

2. The semiconductor package system according to claim 1, wherein the at least one stiffener element is constructed based on a determined warpage of the semiconductor package during an assembly process involving elevated temperatures.

3. The semiconductor package system according to claim 2, wherein the at least one stiffener element is further constructed based on a determined direction the semiconductor package deforms during the assembly process involving elevated temperatures.

4. The semiconductor package system according to claim 1, wherein the at least one stiffener element is attached to the first side of the substrate covering the at least one semiconductor device and the substrate.

5. The semiconductor package system according to claim 1, wherein the at least one stiffener element is provided around a perimeter of the first side of the substrate leaving the first side of the at least one semiconductor device uncovered.

6. The semiconductor package system according to claim 1, wherein the at least one stiffener element is provided within the substrate positioned between the first and second sides of the substrate.

7. The semiconductor package system according to claim 1, wherein the at least two metal elements includes at least two metals.

8. The semiconductor package system according to claim 1, wherein the at least two metal elements includes at least two metal alloys.

9. The semiconductor package system according to claim 1, wherein the at least two metal elements includes a combination of at least a metal and a metal alloy.

10. The semiconductor package system according to claim 1, wherein the at least two metal elements are joined together at least by friction, friction welding, brazing, soldering, sintering, adhesive bonding or fastening.

11. A device, comprising:
a circuit board having a first side and a second side; and
a semiconductor package system provided on the first side of the circuit board, the semiconductor package system including:
a semiconductor package including:
at least one semiconductor device having a first side and a second side; and
a substrate having a first side and a second side,
wherein the second side of the at least one semiconductor device is positioned on the first side of the substrate; and
at least one stiffener element provided on the semiconductor package,
wherein the at least one stiffener element includes at least two metal elements having different coefficients of thermal expansion joined together.

12. The device according to claim 11, wherein the at least one stiffener element is constructed based on a determined warpage of the semiconductor package during an assembly process involving elevated temperatures.

13. The device according to claim 12, wherein the at least one stiffener element is further constructed based on a determined direction the semiconductor package deforms during the assembly process involving elevated temperatures.

14. The device according to claim 11, wherein the at least two metal elements are joined together at least by friction, friction welding, brazing, soldering, sintering, adhesive bonding or fastening.

15. The device according to claim 11, wherein the at least one stiffener element is attached to the first side of the substrate covering the at least one semiconductor device and the substrate.

16. The device according to claim 11, wherein the at least one stiffener element is provided around a perimeter of the first side of the substrate leaving the first side of the at least one semiconductor device uncovered.

17. The device according to claim 11, wherein the at least one stiffener element is provided within the substrate positioned between the first and second sides of the substrate.

18. A method for forming a semiconductor package system, comprising:
providing a substrate;
providing at least one semiconductor device;
connecting the at least one semiconductor device to the substrate to form a semiconductor package;
determining a warpage of the semiconductor package during an assembly process involving elevated temperatures;
constructing at least one stiffener element based on the determined warpage during the assembly process involving elevated temperatures; and
providing the at least one stiffener element on the semiconductor package, wherein the at least one stiffener element comprises at least two metal elements having different coefficients of thermal expansion joined together.

19. The method according to claim 18, further comprising adjusting the at least one stiffener element by varying a thickness of the at least one of the two metal elements to obtain a desired shape and degree of bend for the at least one stiffener element.

20. The method according to claim 18, further comprising constructing the at least one stiffener element based on a determined direction and degree the semiconductor package deforms during the assembly process involving elevated temperatures.
